(19) United States
(12) Patent Application Publication
(10) Pub. No.: US 2013/0153282 A1
(43) Pub. Date: Jun. 20, 2013

(54) PRINTED CIRCUIT BOARD

(71) Applicant: Yi-Yen CHIANG, Taipei City (TW)

(72) Inventor: Yi-Yen CHIANG, Taipei City (TW)

(73) Assignee: MSI COMPUTER(SHENZHEN)CO., LTD., Shenzhen City (CN)

(21) Appl. No.: 13/529,580

(22) Filed: Jun. 21, 2012

(30) Foreign Application Priority Data
Dec. 20, 2011 (TW) 100224059

(51) Int. Cl. H05K 1/11

(52) U.S. Cl. 174/263

(57) ABSTRACT

A printed circuit board including a board, a plating layer and a solder mask layer is provided. The board has a plated through hole for inserting a termination into the board. The plated through hole passes through a surface of the board. An annual ring around the plated through hole covers the surface of the board. The plating layer is formed in the plated through hole and electrically connected to the annual ring. The solder mask layer covers the surface of the board and a portion of the outer circle of the annual ring. The plated through hole and other portion of the outer circle of the annual ring are exposed in an opening of the solder mask layer.

This application claims the benefit of Taiwan application Serial No. 100224059, filed Dec. 20, 2011, the subject matter of which is incorporated herein by reference.

### BACKGROUND OF THE INVENTION

1. Field of the Invention

The invention relates in general to a printed circuit board, and more particularly to a printed circuit board capable of enhancing the quality of the soldering between terminations of elements and annular rings so as to increase the yield rate of electronic products under the circumstance that the solder bridge is free.

2. Description of the Related Art

As the design of electronic products is directed towards lightweight, slimness and compactness, the design of the printed circuit boards and electronic elements disposed inside electronic products is also directed towards high density and miniaturization. Conventionally, the annular rings of a printed circuit board and the terminations of an electronic element may be soldered and become electrically connected to each other. Most of the conventional solders wave-soldered on the annular rings and the terminations disposed in the annular rings are made from a lead solder material, and particularly, the solder has Sn/Pb eutectic solder properties. The alloys that melt between 180˜190° C. have excellent performance in terms of wettability, tin spreading, and solderability.

However, lead, which has been listed as one of the top ten dangerous environment toxicants, is hazardous to children's growth and detrimental to people's health. EU, Japan and many countries have set various regulations (such as WEEE & RoHS directives), and have banned the use of lead solder and the products using the same since 2006. The printed circuit board cannot exclude itself from the trend of lead-free. Apart from the problem of high melting temperature (around 260˜270° C.), the lead-free solder material has high cohesion and poor liquidity and often makes solder bridge, and the copper foil in the plated through hole may be damaged and crack during the contraction and expansion due to the high melting temperature of the lead-free solder material. Besides, when the electronic product is serviced with solder tools, the copper foil (the annual ring) may easily be thinned and dissolved by tin of the lead-free solder and ends up with insufficient thickness and may thus be peeled off easily. Consequently, the soldering quality is affected.

Referring to FIGS. 1A and 1B, a cross-sectional view along a cross-sectional line I-I and a bottom view of a printed circuit board having short-circuiting at solder bridge during the wave soldering process are illustrated respectively. When a wave soldering process is performed on the bottom of the printed circuit board 11, high temperature liquid solder erupts and forms a crest, which contacts the bottom of the printed circuit board 11 in a proceeding direction and often results in solder bridge between the terminations 10. To solve the short-circuiting, the solder bridge is desoldered manually with a soldering iron. As indicated in FIG. 1B, the terminations 10 are normally arranged row by row and are perpendicular to the proceeding direction (the Y-axial direction) of the printed circuit board 11. The solder bridge may easily occur to the printed circuit board 11 when two terminations 10 of two adjacent columns concurrently contact the crest of the solder 12 in a horizontal direction (the X-axial direction). As indicated in FIG. 1B, when the crest of the solder 12 contacts the terminations 10 stood at the end of row, the termination 10 will robber and draw the extra solder to a place where no solder bridge should be formed. As a result, the solder bridge may easily occur to the printed circuit board 11 between two adjacent terminations 10 in the vertical direction (the Y-axial direction). The occurrence of solder bridge will affect the soldering quality, and needs to be resolved.

### SUMMARY OF THE INVENTION

The invention is directed to a printed circuit board. When it is assured that the solder bridge is free, the wetting area of the annual ring is sufficient, and the annual ring is effectively suppressed to avoid the annual ring covered by solder being dragged and peeled off by the operating personnel or being dissolved by the solder. Thus, the soldering quality is improved.

According to one embodiment of the present invention, a printed circuit board including a board, a plating layer and a solder mask layer is provided. The board has a plated through hole for inserting a termination into the board. The plated through hole passes through a surface of the board. An annual ring around the plated through hole covers the surface of the board. The plating layer is formed in the plated through hole and electrically connected to the annual ring. The solder mask layer covers the surface of the board and a portion of the outer circle of the annual ring. The plated through hole and other portion of the outer circle of the annual ring are exposed in an opening of the solder mask layer.

According to another embodiment of the present invention, a printed circuit board including a board, a plating layer and a solder mask layer is provided. The board has a first plated through hole and a second plated through hole for inserting two terminations into the board. The first and the second plated through holes respectively pass through a surface of the board. First and second annual rings around the first and the second plated through holes respectively cover the surface of the board. The plating layer is formed in the first and the second plated through holes and electrically connected to the first and the second annual rings respectively. The solder mask layer covers the surface of the board and portions of the outer circles of the first and the second annual rings. The first plated through hole and other portion of the outer circle of the first annual ring are exposed in a first opening of the solder mask layer. The second plated through hole and other portion of the outer circle of the second annual ring are exposed in a second opening of the solder mask layer.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A and 1B respectively illustrate a cross-sectional view along a cross-sectional line I-I and a bottom view of a printed circuit board having short-circuiting at solder bridge when performing wave soldering;

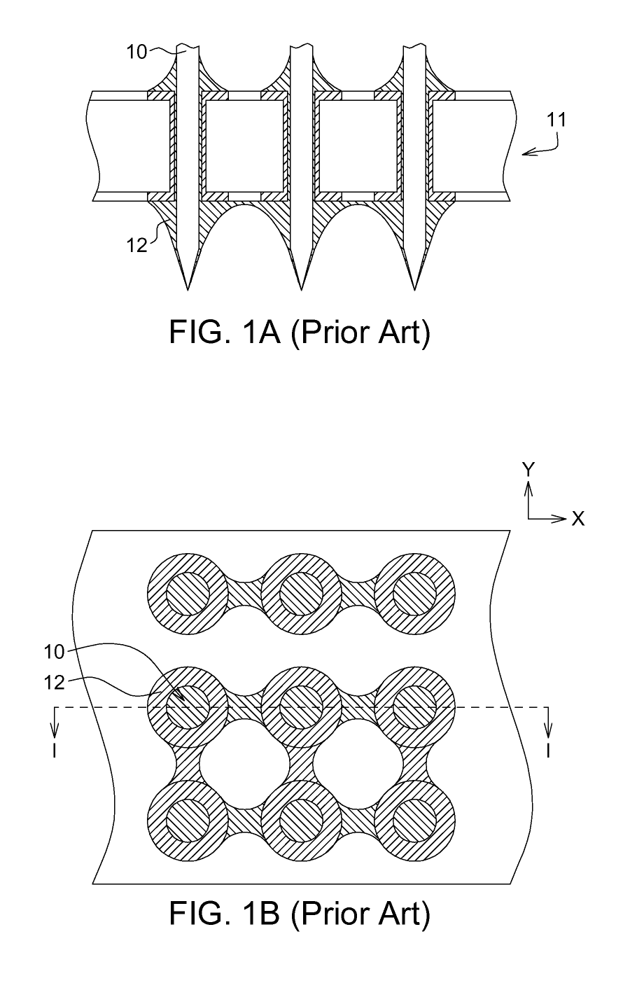

FIGS. 2A and 2B respectively illustrate a schematic diagram and a cross-sectional view along a cross-sectional line A-A of a printed circuit board according to an embodiment of the disclosure;

FIGS. 3A and 3B illustrate two embodiments in which solder mask cover bare copper (i.e. the annual ring) respectively;

FIGS. 4A˜4C respectively illustrate embodiments of several covering portions arranged at an equal distance;

FIG. 5 illustrates a schematic diagram of a board on which two plated through holes are adjacent and the effective distance between two annual rings is increased by a solder mask layer;

FIGS. 6A and 6B illustrate two embodiments in which solder mask cover bare copper (i.e. annual ring) respectively;

FIGS. 7A˜7C respectively illustrate embodiments in which several covering portions are arranged at an equal distance;

FIG. 8 illustrates a schematic diagram of a board on which two plated through holes are adjacent and the effective distance between two annual rings is increased by a solder mask layer;

FIG. 9A and 9B respectively illustrate a cross-sectional view along a cross-sectional line C-C and a bottom view of a printed circuit board preventing from solder bridge during the wave soldering process.

### DETAILED DESCRIPTION OF THE INVENTION

According to the printed circuit board of the present embodiment, a solder mask layer covers a portion of the outside circle of the annual ring, and other portion of the outside circle is exposed in an opening of the solder mask layer. Consequently, the solder bridge is less likely to happen, and the solder mask layer effectively suppresses a copper foil (the annual ring) to avoid the copper foil covered by solder being dragged and peeled off by the operating personnel when performing heating service with soldering iron. As a portion of the outside circle of the annual ring is covered by the solder mask layer, the copper foil is not easily dissolved by the solder and the soldering quality is thus improved.

A number of embodiments are disclosed below for elaborating the disclosure. However, the embodiments of the disclosure are for detailed descriptions only, not for limiting the scope of protection of the disclosure.

### First Embodiment

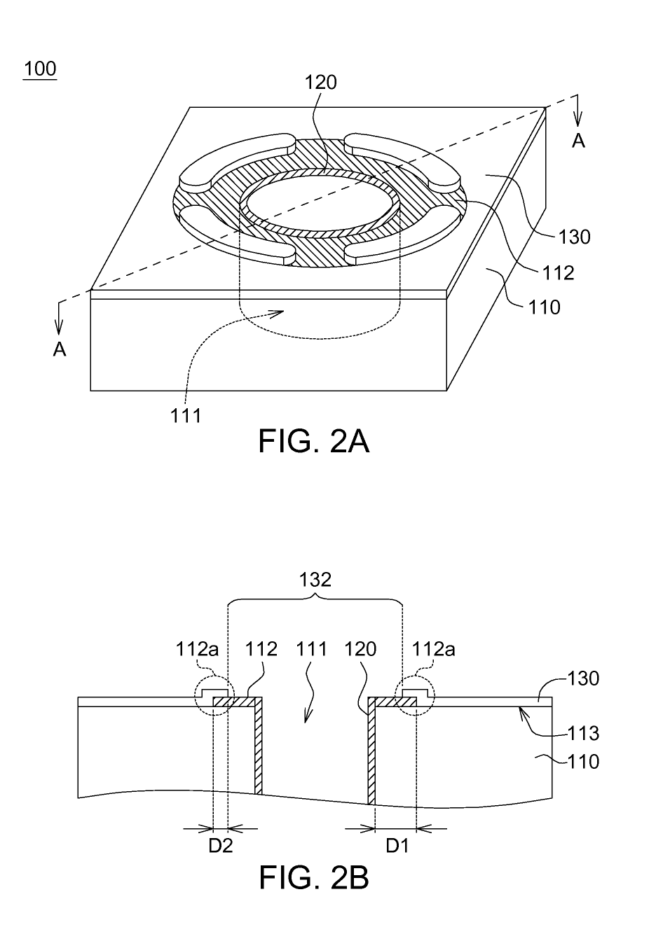

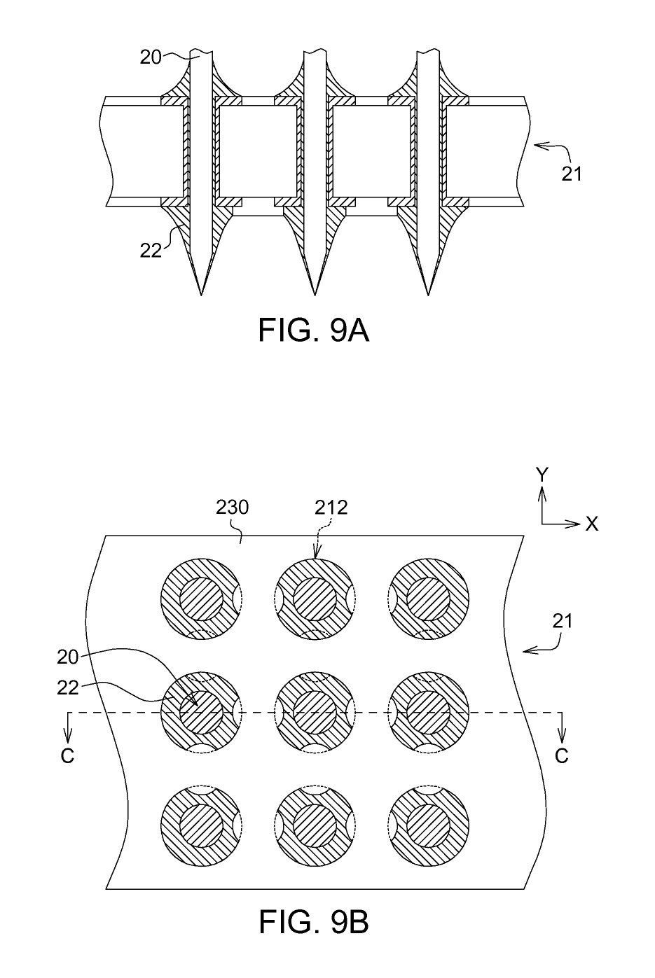

FIGS. 2A and 2B respectively illustrate a schematic diagram and a cross-sectional view along a cross-sectional line A-A of a printed circuit board according to an embodiment of the disclosure. The printed circuit board 100 includes a board 110, a plating layer 120 and a solder mask layer 130. The board 110, being an electrical insulator, has a plated through hole 111 for inserting a termination into the board 110. The diameter of the plated through hole 111 is about 40 mil, and the plating layer 120 whose thickness is about 1 mil may be formed in the plated through hole 111. Preferably but not restrictively, the plating layer 120 is made from copper. In addition, the plated through hole 111 passes through a surface 113 of the board 110, and an annual ring 112 (such as a copper foil) around the plated through hole 111 covers the surface 113 of the board 110. The inner wall of the annual ring 112 is electrically connected with the plating layer 120. The outer surface of the annual ring 112 outwardly extends a predetermined margin D1 (such as 6 mil) from the sidewall of the plated through hole 111, such that the wetting area on the outer surface of the annual ring 112 is sufficient. The terminations of the elements are not illustrated in FIG. 2B. As indicated in FIG. 9A, each termination 20 passes through the plated through holes of the board 21 from the top of the board 21 and is projected from the bottom of the board 21. Then, the wave soldering wetting process is performed to cover the solder 22 on the annual ring for fixing each termination 20 in the plated through hole and electrically connecting each termination 20 to the annual ring. The solder 22 may be a lead solder or a lead-free solder, and preferably is realized by a lead-free solder containing tin, copper and silver to meet the requirement of environmental conservation.

Referring to FIG. 2A. The solder mask layer 130 covers a surface 113 of the board 110. The solder mask layer 130 only covers a portion of the outside circle of the annual ring 112, and other portion of the outside circle is exposed in the opening 132 of the solder mask layer 130. As indicated in FIG. 2B, a portion of the outside circle of the annual ring 112 is covered by the solder mask layer 130. The portion of the outside circle of the annual ring 112 covered by the solder mask layer 130 (that it, the covering portion 112a) has a margin D2 in the radial direction of the annual ring 112. The margin D2 is about a half of the margin D1 of the annual ring 112. For example, the margin D1 of the annual ring 112 is 6 mil, and the margin D2 of the covering portion 112a in the radial direction of the annual ring 112 is about 2˜3 mil. In the present embodiment, the solder mask layer 130 covers the annual ring 112, not only reducing the likelihood of solder bridge but further effectively suppressing and avoiding the copper foil (the annual ring 112) being dragged and peeled when the copper foil is covered by solder . Besides, as a portion of the outside circle of the annual ring 12 is covered by the solder mask layer 130, the copper foil is not easily dissolved by tin in the lead-free solder and the soldering quality is thus improved.

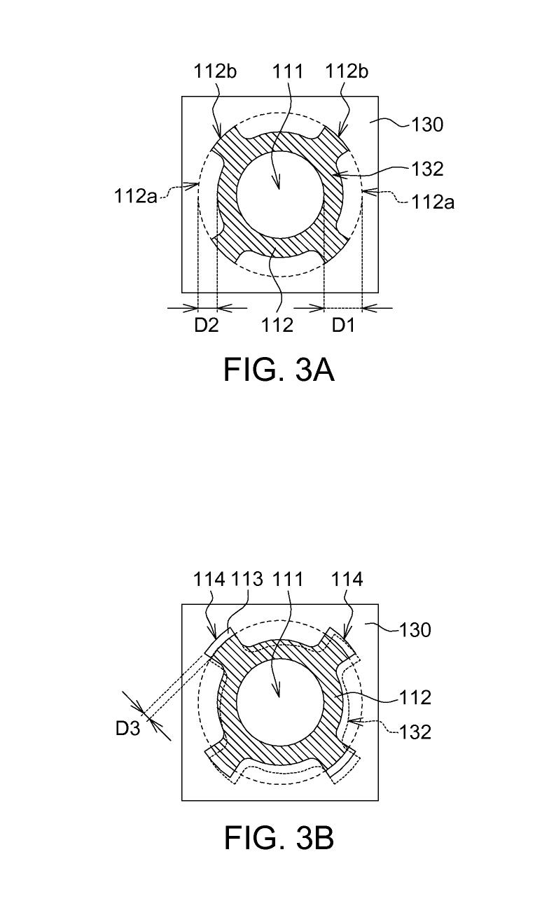

Referring to FIG. 3A and 3B, two embodiments in which the solder mask layer 130 covers the annual ring 112 are shown. The portion of the outside circle of the annual ring 112 covered by the solder mask layer 130 is divided into four covering portions 112a at an equal distance. The portion of the outside circle of the annual ring 112 exposed in the opening 132 is divided into four exposing portions 112b at an equal distance. The covering portions 112a and the exposing portions 112b are disposed in alternating sequence. That is, each covering portion 112a is interposed between two exposing portions 112b disposed at two lateral sides of the covering portion 112a. The ratios of the lengths of a covering portion 112a and an exposing portion 112b to the circumference of the outside circle of the annual ring 112 may be adjusted according to actual needs. Preferably, the ratios are 1/4˜1/16 of the circumference of the outside circle of the annual ring 112. As indicated in FIG. 3A, each covering portion 112a occupies 1/6 of the circumference of the outside circle of the annual ring 112, and each exposing portion 112b occupies 1/12 of the circumference of the outside circle of the annual ring 112. If the quantity of the covering portions 112a is not four (such as one or two), the ratio of the length of a covering portion to the circumference of the outside circle of the annual ring 112 varies accordingly. Therefore, the above ratio range is merely one exemplification, and the disclosure is not limited thereto.

As indicated in FIG. 3B, the opening 132 of the solder mask layer 130 exposes the plated through hole 111 and a portion of the outer circle of the annual ring 112 as well as a portion of the board surface 113 around the outside circle of the annual ring 112. The portion (that is, the opening aligning portion 114) of the surface around the outside circle of the annual ring 112 exposed in the opening 132 has a margin D3 in the radial direction of the annual ring 112. The margin D3 is about a half of the margin D1 of the annual ring 112. For example, the margin D1 of the annual ring 112 is 6 mil, and the margin D3 of the opening aligning portion 114 in the radial direction of the annual ring 112 is about 2˜3 mil, which is equivalent to the maximum tolerance of the annual ring 112 with respect to the misregistration of the solder mask layer 130. In the present embodiment, when the misregistration of the solder mask layer 130 on the board 110 is shifted by 2 mil (as indicated by dotted lines, the opening 132 of the solder mask layer 130 is not aligned with the central point of the plated through hole 111), a portion of the outside circle of the annual ring 112 is still exposed within the reserved region of the shifted opening 132 (that is, the region within which a portion of the surface 113 of the board 110 is originally exposed). Thus, the problem of cold soldering or under soldering which occurs when the area of the annual ring 112 covered by the solder mask layer 130 is increased can thus be avoided. Since the possibly shifted region of the opening 132 is reserved in the present embodiment, the wetting area on the outer surface of the annual ring 112 is sufficient and is created by the solder contour extending over the edge of the solderable termination area, and the soldering quality can thus be improved.

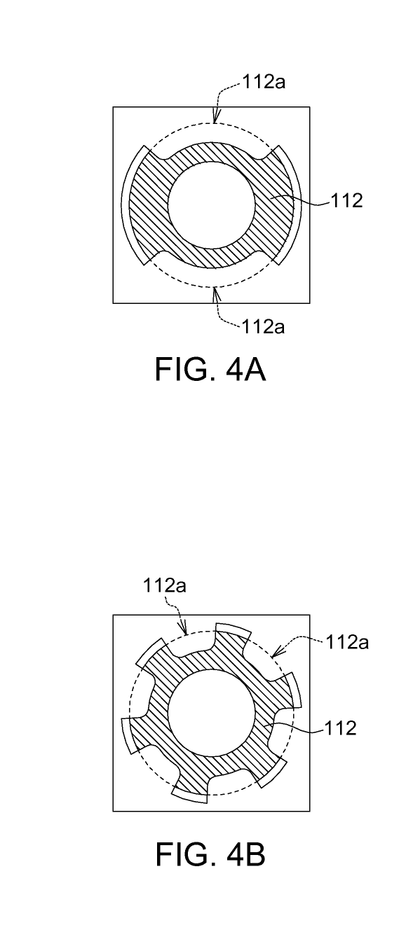

As indicated in FIG. 3A and 3B, when four covering portions 112a are arranged at an equal distance, the phase angle between every two adjacent covering portions 112a is 90 degrees. The arrangement of covering portions 112a is not limited to four covering portions 112a arranged at an equal distance, and may also be realized by any quantity of covering portions 112a arranged at an equal or an unequal distance. Referring to FIGS. 4A˜4C. FIG. 4A illustrates two covering portions 112a of the annual ring 112 arranged at an equal distance, wherein the phase angle between two covering portions 112a is 180 degrees. FIG. 4B illustrates six covering portions 112a of the annual ring 112 arranged at an equal distance, wherein the phase angle between two covering portions 112a is 60 degrees. FIG. 4C illustrates eight covering portions 112a of the annual ring 112 arranged at an equal distance, wherein the phase angle between two covering portions 112a is 45 degrees. The ratios of the lengths of a covering portion 112a and an exposing portion 112b to the circumference of the outside circle of the annual ring 112 can be adjusted according to actual needs. Preferably, the ratios are 1/4˜1/16 of the circumference of the outside circle of the annual ring 112.

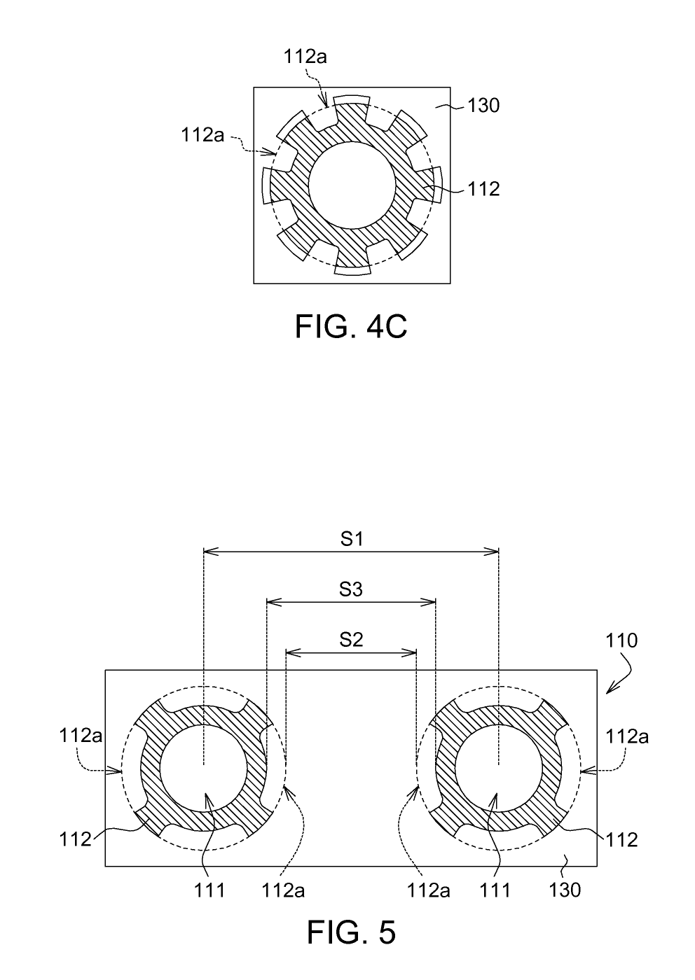

Referring to FIG. 5, a schematic diagram of a board on which two plated through holes 111 are adjacent and the effective distance between two annual rings 112 is increased by a solder mask layer is shown. The board 110 has two plated through holes 111 (the first and the second plated through holes), and the pitch S1 between the two plated through holes 111 is 100 mil, for example. Two annual rings 112 (the first and the second annual rings) disposed around two plated through holes 111 cover the surface 113 of the board 110, and the shortest distance S2 between the two annual rings 112 is 48 mil for example, within which the solder bridge may be happened. The solder mask layer 130 covers the board surface between two annual rings 112 and a portion (that is, the covering portion 112a) of the outside circle of two annual rings 112 such that the effective distance S3 between the two annual rings 112 is increased and becomes larger than the smallest distance of the solder bridge. Thus, the likelihood of solder bridge between two annual rings 112 is reduced.

### Second Embodiment

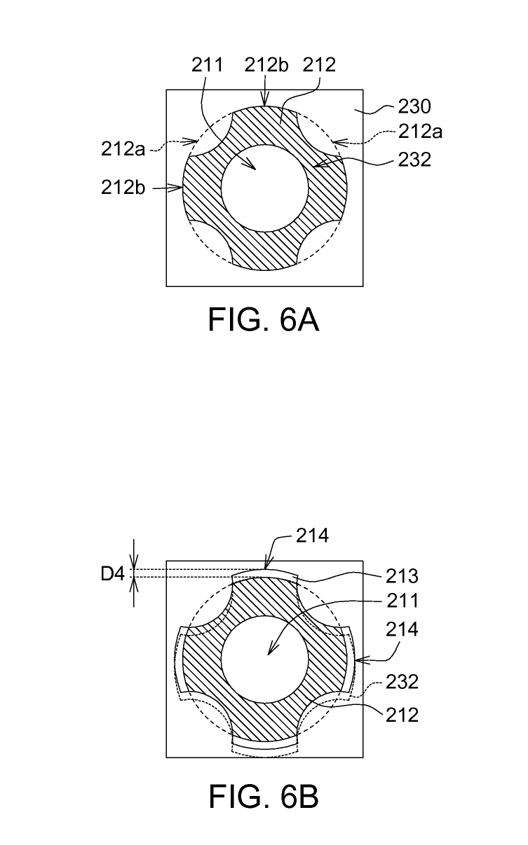

Referring to FIG. 6A and 6B, two embodiments in which a solder mask layer covers the annual ring are respectively shown. The portion of the outside circle of the annual ring 212 covered by the solder mask layer 230 is divided into four covering portions 212a at an equal distance. The covering portions 212a of the present embodiment are leave-shaped, and the covering portions 112a of the first embodiment are strip-shaped. The portion of the outside circle of the annual ring 212 exposed in the opening 232 is divided into four exposing portions 212b at an equal distance. The covering portions 212a and the exposing portions 212b are disposed in alternating sequence. That is, each covering portion 212a is interposed between two exposing portions 212b disposed at two lateral sides of the covering portion 212a. The ratios of the lengths of a covering portion 212a and an exposing portion 112b to the circumference of the outside circle of the annual ring 212 may be adjusted according to actual needs. Preferably, the ratio is 1/4˜1/16 of the outside circle of the circumference of the annual ring 212. As indicated in FIG. 6A, each covering portion 212a occupies 1/8 of the circumference of the outside circle of the annual ring 212, and each exposing portion 212b occupies 1/8 of the circumference of the outside circle of the annual ring 212. If the quantity of the covering portion 212a is not four (such as one or two), the ratio of the length of a covering portion to the circumference of the outside circle of the annual ring 212 varies accordingly. Therefore, the above ratio range is merely one exemplification, and the disclosure is not limited thereto.

As indicated in FIG. 6B, the opening 232 of the solder mask layer 230 exposes the plated through hole 211 and a portion of the outer circle of the annual ring 212 as well as a portion of the board surface 213 around the outside circle of the annual ring 212. The portion (that is, the opening aligning portion 214) of the surface around the outside circle of the annual ring 212 exposed in the opening 232 has a margin D4 in the radial direction of the annual ring 212. The margin D4 is about a half of the margin D1 of the annual ring 212. For example, the margin D1 of the annual ring 212 is 6 mil, and the margin D4 of the opening aligning portion 214 in the radial direction of the annual ring 212 is about 2˜3 mil, which is equivalent to the maximum tolerance of the annual ring 212 with respect to the misregistration of the solder mask layer 230. In the present embodiment, when the misregistration of the solder mask layer 230 on the board 210 is shifted by 2 mil (as indicated by dotted lines, the opening 232 of the solder mask layer 230 is not aligned with the central point of the plated through hole 211), a portion of the outside circle of the annual ring 212 is still exposed within the reserved region of the shifted opening 232 (that is, the region within which a portion of the surface 213 of the board 210 is originally exposed). Thus, the problem of cold soldering or under soldering which occurs when the area of the annual ring 212 covered by the solder mask layer 230 is increased can thus be avoided. Since the possibly shifted region of the opening 232 is reserved in the present embodiment, the wetting area on the outer surface of the annual ring 212 is sufficient and is created by the solder contour extending over the edge of the solderable termination area, and the soldering quality can thus be improved.

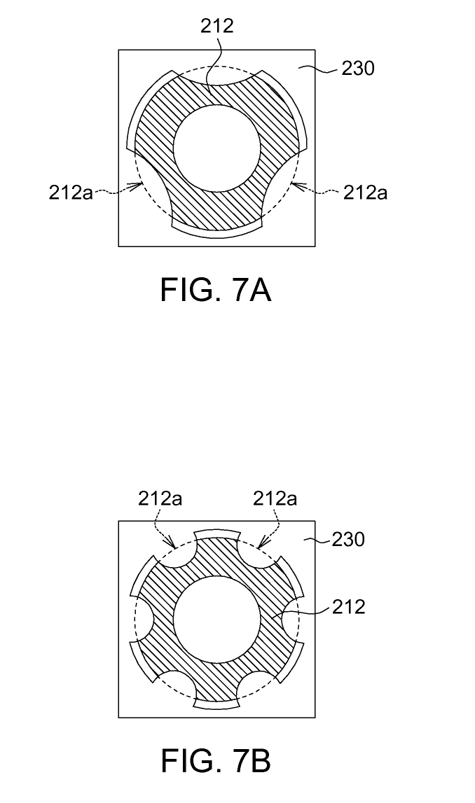

As indicated in FIG. 6A and 6B, when four covering portions 212a are arranged at an equal distance, the phase angle between every two adjacent covering portions 212a is 90 degrees. The arrangement of covering portions 212a is not limited to four covering portions 212a arranged at an equal distance, and may also be realized by any quantity of covering portions 212a arranged at an equal or unequal distance. Referring to FIGS. 7A˜4C. FIG. 7A illustrates three covering portions 212a of the annual ring 212 arranged at an equal distance, wherein the phase angle between two covering portions 212a is 120 degrees. FIG. 7B illustrates six covering portions 212a of the annual ring 212 arranged at an equal distance, wherein the phase angle between two covering portions 212a is 60 degrees. FIG. 7C illustrates eight covering portions 212a of the annual ring 212 arranged at an equal distance, wherein the phase angle between two covering portions 212a is 45 degrees. The ratios of the lengths of a covering portion 212a and an exposing portion 212b to the circumference of the outside circle of the annual ring 212 may be adjusted according to actual needs. Preferably, the ratios are 1/4˜1/16 of the circumference of the outside circle of the annual ring 212.

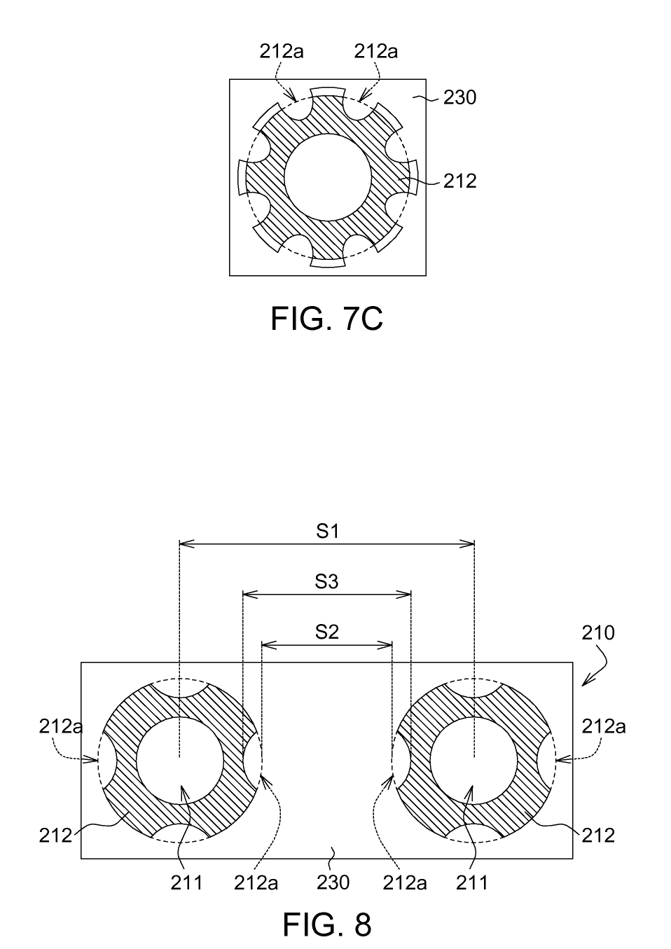

Referring to FIG. 8, a schematic diagram of a board on which two plated through holes 211 are adjacent and the effective distance between two annual rings 212 is increased by a solder mask layer is shown. The board 210 has two plated through holes 211 (the first and the second plated through holes), and the pitch S1 between the two plated through holes 211 is 100 mil, for example. Two annual rings 212 (the first and the second annual rings) disposed around two plated through holes 211 cover the surface 213 of the board 210, and the shortest distance S2 between the two annual rings 212 is 48 mil, within which the solder bridge may be happened. The solder mask layer 230 covers the board surface 213 between two annual rings 212 and a portion (that is, the covering portion 212a) of the outside circle of two annual rings 212 such that the effective distance S3 between two annual rings 212 is increased and becomes larger than the smallest distance of the solder bridge. Thus, the likelihood of solder bridge between two annual rings 212 is reduced.

Referring to FIG. 9A and 9B, a cross-sectional view along a cross-sectional line C-C and a bottom view of a printed circuit board 21 preventing from solder bridge during the wave soldering process are respectively shown. When the wave soldering process is performed on the bottom of the printed circuit board 21, a portion of the outside circle of the annual ring 212 in the horizontal direction (the X-axial direction) is covered by the solder mask layer 230, and the effective distance between two annual rings 212 is increased. Thus, when two terminations 20 in two adjacent columns concurrently contacts the crest of the solder 22, the pitch between the two terminations 20 is wide enough to avoid solder bridge. As indicated in FIG. 9B, a portion of the outside circle of the annual ring 212 is covered by the solder mask layer 230 in the vertical direction (the Y-axial direction). When the crest of the solder 22 contacts the termination 20 stood at the end of row, the termination 20 will not robber and draw the extra solder to a place where no solder bridge should be formed. As a result, the solder bridge is less likely to occur between two adjacent terminations 20 in the vertical direction (the Y-axial direction), and the soldering quality can thus be improved. As indicated in FIG. 9B, a portion of annual ring 212 may have only one single side or two opposite sides covered by the solder mask layer 230 or may have two adjacent sides covered by the solder mask layer 130. Thus, the portion (or quantity) of the outside circle of the annual ring 212 covered by the solder mask layer 230 may be adjusted according to the location of the portion being covered. When it is assured that the solder bridge is free, the area covered by the solder mask layer 230 is reduced so as to increase the wetting area of the annual ring 212. For example, the solder of the annular annual rings 212 between the first row and the second row has relatively smaller reflux and is less likely to result in short-circuiting. Meanwhile, the area of two adjacent annual rings 212 covered by the solder mask layer 230 in the vertical direction (the Y-axial direction) is reduced (the portion not covered by the solder mask layer 230 is denoted in dotted lines) so as to improve the soldering quality.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A printed circuit board, comprising:
a board having a plated through hole for inserting a termination into the board, wherein the plated through hole passes through a surface of the board, and an annual ring around the plated through hole covers the surface of the board;
a plating layer formed in the plated through hole and electrically connected to the annual ring; and
a solder mask layer covering the surface of the board and a portion of an outer circle of the annual ring, wherein the plated through hole and other portion of the outer circle of the annual ring are exposed in an opening of the solder mask layer.

2. The printed circuit board according to claim 1, wherein the opening of the solder mask layer further exposes a portion of the surface around the outside circle of the annual ring.

3. The printed circuit board according to claim 2, wherein the portion of the outside circle of the annual ring covered by the solder mask layer forms a covering portion, the other portion of the outside circle of the annual ring exposed in the opening forms two exposing portions, and the covering portion is interposed between two exposing portions disposed at two lateral sides of the covering portion.

4. The printed circuit board according to claim 3, wherein a portion of the surface around the outside circle of the annual ring exposed in the opening forms two opening aligning portions, and the covering portion is interposed between the two opening aligning portions disposed at two lateral sides of the covering portion.

5. The printed circuit board according to claim 3, wherein a margin of the covering portion in the radial direction of the annual ring is about a half of a margin of the annual ring.

6. The printed circuit board according to claim 4, wherein margins of the two opening aligning portions in the radial direction of the annual ring are about a half of a margin of the annual ring.

7. The printed circuit board according to claim 4, wherein margins of the opening aligning portions in the radial direction of the annual ring are equivalent to a maximum tolerance of the annual ring with respect to the misregistration of the solder mask layer.

8. The printed circuit board according to claim 1, wherein the outside circle of the annual ring is divided by the solder mask layer into several covering portions at an equal distance, and the outside circle of the annual ring is divided by the opening into several exposing portions at an equal distance, and the covering portions and the exposing portions are disposed in alternating sequence.

9. The printed circuit board according to claim 8, wherein each covering portion and each exposing portion respectively occupy 1/4˜1/16 of the circumference of the outside circle of the annual ring.

10. The printed circuit board according to claim 8, wherein when the quantity of the covering portions is four and the quantity of the exposing portions is also four, each covering portion and each exposing portion respectively occupy 1/6˜1/8 of the circumference of the outside circle of the annual ring.

11. The printed circuit board according to claim 8, further comprising a solder, wherein the termination is fixed in the plated through hole and electrically connected to the annual ring by the solder.

12. A printed circuit board, comprising:
a board having a first plated through hole and a second plated through hole for inserting two terminations into the board, wherein the first and the second plated through holes respectively pass through a surface of the board, and a first and a second annual rings around the first and the second plated through holes respectively cover the surface of the board;
a plating layer formed in the first and the second plated through holes and electrically connected to the first and the second annual rings respectively; and
a solder mask layer covering the surface of the board and a portion of the outer circles of the first and the second annual rings, wherein the first plated through hole and other portion of the outer circle of the first annual ring are exposed in a first opening of the solder mask layer, and the second plated through hole and other portion of the outer circle of the second annual ring are exposed in a second opening of the solder mask layer.

13. The printed circuit board according to claim 12, wherein the first opening of the solder mask layer further exposes a portion of the surface around the outside circle of the first annual ring, and the second opening of the solder mask layer further exposes a portion of the surface around the outside circle of the second annual ring.

14. The printed circuit board according to claim 13, wherein the portions of the outside circles of the first and the second annual rings covered by the solder mask layer respectively form a covering portion, the two covering portions are separated by an interval and are located at two ends of a straight distance between the first and the second annual rings.

15. The printed circuit board according to claim 14, wherein the portion of the outside circle of the first annual ring exposed in the first opening forms two exposing portions, and the portion of the outside circle of the second annual ring exposed in the second opening forms two exposing portions, and each covering portion is correspondingly interposed between two exposing portions disposed at two lateral sides of the covering portion.

16. The printed circuit board according to claim 14, wherein a portion of the surface around the outside circle of the first annual ring exposed in the first opening forms two opening aligning portions, and each covering portion is correspondingly interposed between two opening aligning portions disposed at two lateral sides of the covering portion.

17. The printed circuit board according to claim 14, wherein a margin of each covering portion in the radial directions of the first and the second annual rings is about a half of margins of the first and the second annual rings.

18. The printed circuit board according to claim 16, wherein margins of the two opening aligning portions in the radial directions of the first and the second annual rings are about a half of margins of the first and the second annual rings.

19. The printed circuit board according to claim 16, wherein margins of each two opening aligning portions in the radial directions of the first and the second annual rings are equivalent to a maximum misregistration of the solder mask layer with respect to the first and the second annual rings.

20. The printed circuit board according to claim 12, wherein the outside circle of the first annual ring is divided by the solder mask layer into several covering portions at an equal distance, the outside circle of the first annual ring is divided by the first opening into several exposing portions at an equal distance, and the covering portions and the exposing portions are disposed in alternating sequence.

21. The printed circuit board according to claim 20, wherein each covering portion and each exposing portion respectively occupy 1/4˜1/16 of the circumference of the outside circle of the first annual ring.

22. The printed circuit board according to claim 21, wherein when the quantity of the covering portions is four and the quantity of the exposing portions is also four, each covering portion and each exposing portion respectively occupy 1/6˜1/8 of the circumference of the outside circle of the first annual ring.

23. The printed circuit board according to claim 12, wherein the outside circle of the second annual ring is divided by the solder mask layer into several covering portions at an equal distance, the outside circle of the second annual ring is divided by the second opening into several exposing portions at an equal distance, and the covering portions and the exposing portions are disposed in alternating sequence.

24. The printed circuit board according to claim 23, wherein each covering portion and each exposing portion respectively occupy 1/4˜1/16 of the circumference of the outside circle of the second annual ring.

25. The printed circuit board according to claim 24, wherein when the quantity of the covering portions is four and the quantity of the exposing portions is also four, each covering portion and each exposing portion respectively occupy 1/6˜1/8 of the circumference of the outside circle of the second annual ring.

26. The printed circuit board according to claim 12, further comprising two solders, wherein the two terminations are respectively fixed in the first and the second plated through holes and electrically connected to the first and the second annual rings respectively by each solder.
